(19) United States
(12) Patent Application Publication
(10) Pub. No.: US 2024/0321774 A1
(43) Pub. Date: Sep. 26, 2024

(54) SEMICONDUCTOR DEVICE, METHOD OF MANUFACTURING SEMICONDUCTOR DEVICE, AND SEMICONDUCTOR PACKAGE INCLUDING SEMICONDUCTOR DEVICE

(71) Applicant: SAMSUNG ELECTRONICS CO., LTD., Suwon-si (KR)

(72) Inventors: Kitae Park, Suwon-si (KR); Chiwan Song, Suwon-si (KR); Seonkyu Kim, Suwon-si (KR); Hyunna Bae, Suwon-si (KR); Seungmin Baek, Suwon-si (KR); Yongjae Song, Suwon-si (KR); Joonseok Oh, Suwon-si (KR); Jaewook Jung, Suwon-si (KR); Seokil Hong, Suwon-si (KR)

(21) Appl. No.: 18/399,519

(22) Filed: Dec. 28, 2023

(30) Foreign Application Priority Data
Mar. 24, 2023 (KR) 10-2023-0039005
Apr. 28, 2023 (KR) 10-2023-0056638

(51) Int. Cl. H01L 23/00; H01L 21/02; H01L 21/3205; H01L 23/31; H01L 23/492; H01L 25/065; H10B 80/00

(52) U.S. Cl. CPC H01L 23/562; H01L 21/0214; H01L 21/02249; H01L 21/02252; H01L 21/32055; H01L 23/3135; H01L 23/4926; H01L 24/48; H01L 25/0657; H10B 80/00; H01L 2224/48149; H01L 2224/48227; H01L 2225/06506; H01L 2225/0651; H01L 2225/06513; H01L 2225/06517; H01L 2225/06541; H01L 2225/06562; H01L 2924/3511; H01L 2924/3512

(57) ABSTRACT

The present disclosure relates to semiconductor devices and semiconductor packages. One example semiconductor device includes a crystalline silicon layer, an amorphous silicon layer on the crystalline silicon layer and extending along a first surface of the crystalline silicon layer, and a dielectric layer on the amorphous silicon layer and extending along a surface of the amorphous silicon layer. The dielectric layer includes silicon oxynitride and has compressive stress.

### CROSS-REFERENCE TO RELATED APPLICATIONS

This application claims priority under 35 U.S.C. § 119 to Korean Patent Application Nos. 10-2023-0039005, filed on Mar. 24, 2023, and 10-2023-0056638, filed on Apr. 28, 2023, in the Korean Intellectual Property Office, the disclosures of which are incorporated by reference herein in their entirety.

### BACKGROUND

With the trend of light, thin, and miniaturized semiconductor packages, the thickness of semiconductor devices (e.g., semiconductor chips) provided in a semiconductor package is gradually decreasing. As the thickness of the semiconductor device decreases, the defect of the semiconductor device due to warpage has a greater influence on the reliability of the semiconductor device. Accordingly, various attempts have been made to control and suppress warpage of the semiconductor device while making the semiconductor device thin.

### SUMMARY

The present disclosure relates to semiconductor devices having improved reliability and semiconductor packages including the semiconductor devices.

In some implementations, a semiconductor device includes a crystalline silicon layer, an amorphous silicon layer extending along a first surface of the crystalline silicon layer, and a dielectric layer extending along a surface of the amorphous silicon layer, including silicon oxynitride, and having compressive stress.

In some implementations, a semiconductor package includes a plurality of semiconductor devices stacked in a vertical direction, wherein each of the plurality of semiconductor devices includes a crystalline silicon layer, an amorphous silicon layer extending along a first surface of the crystalline silicon layer, and a dielectric layer extending along a surface of the amorphous silicon layer, including silicon oxynitride, and having compressive stress.

In some implementations, a semiconductor package includes a first redistribution structure including a first redistribution pattern, a semiconductor device on the first redistribution structure, a molding layer disposed on the first redistribution structure and configured to cover the semiconductor device, a second redistribution structure disposed on the molding layer and including a second redistribution pattern, and a vertical connection conductor electrically connecting the first redistribution pattern to the second redistribution pattern, wherein the semiconductor device includes a crystalline silicon layer having first and second surfaces opposite to each other, the second surface facing the first redistribution structure, an amorphous silicon layer extending along the first surface of the crystalline silicon layer and contacting the first surface of the crystalline silicon layer, a dielectric layer extending along a surface of the amorphous silicon layer on the amorphous silicon layer, including silicon oxynitride, and having compressive stress, and an interconnect structure between the second surface of the crystalline silicon layer and the first redistribution structure, and including a wiring pattern.

In some implementations, a manufacturing method of a semiconductor device includes forming an amorphous silicon layer on a crystalline silicon layer, and forming a dielectric layer on the amorphous silicon, wherein the dielectric layer includes silicon oxynitride.

### BRIEF DESCRIPTION OF THE DRAWINGS

Implementations will be more clearly understood from the following detailed description taken in conjunction with the accompanying drawings.

FIG. 1 is a cross-sectional view illustrating an example of a semiconductor device.

FIG. 2 is a diagram showing an example of a region indicated by “EX1” in FIG. 1.

FIG. 3 is a diagram showing example warpage control by a dielectric layer of a semiconductor device.

FIG. 4 is a flowchart illustrating an example of a method of manufacturing a semiconductor device.

FIGS. 5A to 5C are cross-sectional views illustrating an example of a method of manufacturing a semiconductor device.

FIG. 6 is a cross-sectional view illustrating an example of a semiconductor device.

FIGS. 7A to 7F are cross-sectional views illustrating another example of a method of manufacturing a semiconductor device.

FIG. 8 is a cross-sectional view illustrating another example of a semiconductor package.

FIG. 9 is a cross-sectional view illustrating another example of a semiconductor device.

FIGS. 10A to 10D are cross-sectional views illustrating another example of a method of manufacturing a semiconductor device.

FIG. 11 is a cross-sectional view illustrating another example of a semiconductor package.

FIG. 12 is a cross-sectional view illustrating another example of a semiconductor package.

### DETAILED DESCRIPTION

Hereinafter, example implementations will be described in detail with reference to the accompanying drawings. The same reference numerals are used for the same components in the drawings, and duplicate descriptions thereof are omitted.

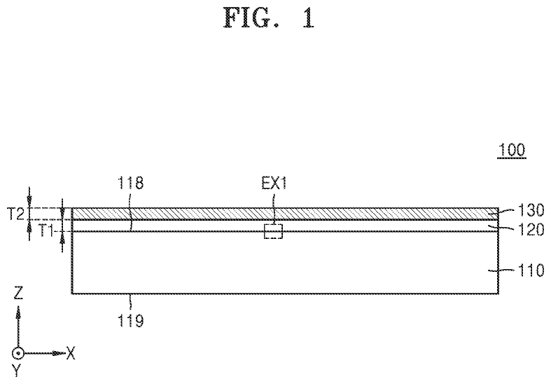

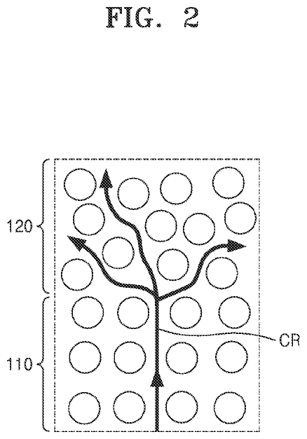

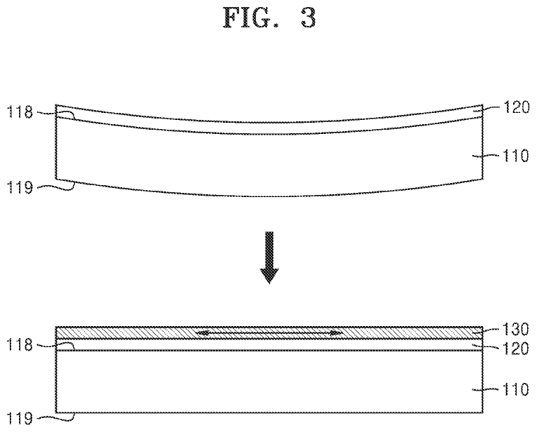

FIG. 1 is a cross-sectional view illustrating an example of a semiconductor device 100. FIG. 2 is a diagram illustrating an example of a region indicated by “EX1” in FIG. 1. FIG. 3 is a diagram showing example warpage control by a dielectric layer 130 of the semiconductor device 100.

Referring to FIGS. 1 to 3, the semiconductor device 100 may include a crystalline silicon layer 110, an amorphous silicon layer 120, and a dielectric layer 130. For example, the semiconductor device 100 may be a semiconductor chip, a package substrate, or an interposer substrate but is not limited thereto.

The crystalline silicon layer 110 may have a substantially flat plate shape. The crystalline silicon layer 110 may include a first surface 118 and a second surface 119 opposite to each other, and the first surface 118 and the second surface 119 of the crystalline silicon layer 110 may each include a plane. The thickness of the crystalline silicon layer 110 may range from several to hundreds of micrometers.

The amorphous silicon layer 120 may extend along the first surface 118 of the crystalline silicon layer 110 and at least partially cover the first surface 118 of the crystalline silicon layer 110. In example implementations, the amorphous silicon layer 120 may entirely cover the first surface 118 of the crystalline silicon layer 110. The amorphous silicon layer 120 may directly contact the first surface 118 of the crystalline silicon layer 110 and contact between the amorphous silicon layer 120, and the crystalline silicon layer 110 may be continuous along the extension direction of the amorphous silicon layer 120. As shown in FIG. 2, the amorphous silicon layer 120 is configured to relieve or disperse stress applied or generated in the semiconductor device 100, and may be configured to block propagation of cracks CR within the semiconductor device 100.

The amorphous silicon layer 120 may be formed to cover the surface of the crystalline silicon layer 110 through plasma treatment of the surface of the crystalline silicon layer 110. In example implementations, the amorphous silicon layer 120 may be formed by sputtering the crystalline silicon layer 110 using plasma generated from a source gas including argon (Ar).

The amorphous silicon layer 120 may conformally extend along the first surface 118 of the crystalline silicon layer 110 and may have a substantially uniform thickness. The thickness T1 of the amorphous silicon layer 120 may range from several to hundreds of nanometers. In example implementations, the thickness T1 of the amorphous silicon layer 120 may range from about 1 nm to about 200 nm. The time of the plasma treatment process for forming the amorphous silicon layer 120, radio frequency (RF) power for plasma treatment, plasma concentration, and the like may be adjusted so that the thickness T1 of the amorphous silicon layer 120 has a preset target thickness.

The dielectric layer 130 may be provided on the amorphous silicon layer 120. The dielectric layer 130 may be spaced apart from the crystalline silicon layer 110 with the amorphous silicon layer 120 therebetween. The dielectric layer 130 may extend along the surface of the amorphous silicon layer 120 and at least partially cover the surface of the amorphous silicon layer 120. In example implementations, the dielectric layer 130 may entirely cover the surface of the amorphous silicon layer 120. The dielectric layer 130 is in direct contact with the amorphous silicon layer 120, and contact between the dielectric layer 130 and the amorphous silicon layer 120 may be continuous along the extending direction of the dielectric layer 130.

The dielectric layer 130 may be formed to cover the surface of the amorphous silicon layer 120 through plasma treatment of the surface of the crystalline silicon layer 110. In example implementations, the dielectric layer 130 may be formed through a plasma treatment, for example, a low temperature plasma treatment performed at a low temperature (e.g., a temperature of 400° C. or less).

The dielectric layer 130 conformally extends along the first surface 118 of the crystalline silicon layer 110 and may have a substantially uniform thickness. The thickness T2 of the dielectric layer 130 may range from several to hundreds of nanometers. In example implementations, the thickness T2 of the dielectric layer 130 may range from about 1 nm to about 200 nm. The time of a plasma treatment process for forming the dielectric layer 130, RF power for plasma treatment, plasma concentration, and the like may be adjusted so that the thickness T2 of the dielectric layer 130 has a preset target thickness.

The dielectric layer 130 may be configured to control warpage of the semiconductor device 100. For example, the dielectric layer 130 reduces or removes warpage of the semiconductor device 100 by generating stress to offset or suppress stress generated by a difference in coefficient of thermal expansion between components in the semiconductor device 100. In example implementations, the dielectric layer 130 may be configured to have compressive stress or tensile stress.

In example implementations, as shown in FIG. 3, the dielectric layer 130 may have compressive stress. The compressive stress of the dielectric layer 130 is generated by resisting the stress generated in the semiconductor device 100, thereby reducing warpage of the semiconductor device 100.

The dielectric layer 130 may include silicon oxynitride. For example, the dielectric layer 130 may be formed through a plasma treatment configured to react plasma generated from an oxygen-source gas including an oxygen element and a nitrogen-source gas including a nitrogen element to the amorphous silicon layer 120.

In example implementations, in the silicon oxynitride of the dielectric layer 130, a ratio of an oxygen element and a nitrogen element may be controlled. That is, silicon oxynitride of the dielectric layer 130 may be expressed as SiOₓN₍₁₋ₓ₎ (where 0<x<1). To adjust the ratio of the oxygen element and the nitrogen element in the silicon oxynitride of the dielectric layer 130, a ratio between the flow rate of the oxygen-source gas and the flow rate of the nitrogen-source gas used in the plasma treatment process for forming the dielectric layer 130 may be adjusted.

The properties (e.g., compressive stress or thermal expansion coefficient) of the dielectric layer 130 may be adjusted by adjusting the ratio of oxygen elements and nitrogen elements in the silicon oxynitride of the dielectric layer 130. In example implementations, the thermal expansion coefficient of the dielectric layer 130 may be adjusted to a preset target thermal expansion coefficient by adjusting the ratio of the oxygen element and the nitrogen element in the silicon oxynitride of the dielectric layer 130. For example, the coefficient of thermal expansion of the dielectric layer 130 may be increased by increasing the ratio of an oxygen element in silicon oxynitride of the dielectric layer 130.

In example implementations, the dielectric layer 130 may include at least one of a binary compound, a ternary compound, and a quaternary compound in addition to silicon oxynitride. Each of the binary compound, the ternary compound, and the quaternary compound may include elements selected from the group consisting of a silicon element, a nitrogen element, an oxygen element, a hydrogen element, and a mixture thereof.

In example implementations, the dielectric layer 130 may include a binary compound including a silicon element and a nitrogen element.

In example implementations, the dielectric layer 130 may include a ternary compound including a silicon element, a nitrogen element, and a hydrogen element.

In example implementations, the dielectric layer 130 may include a quaternary compound including a silicon element, a nitrogen element, an oxygen element, and a hydrogen element.

In example implementations, the dielectric layer 130 may not include a carbon element. In general, when a dielectric film is formed by thermal chemical vapor deposition (CVD), a carbon element in a precursor is included in the dielectric film. However, the dielectric layer 130 is formed through plasma treatment and may not include carbon.

In FIG. 1, it is illustrated that the amorphous silicon layer 120 and the dielectric layer 130 are formed on the first surface 118 of the crystalline silicon layer 110, but the amorphous silicon layer 120 and the dielectric layer 130 may also be provided on other surfaces of the crystalline silicon layer 110. For example, the semiconductor device 100 may include another amorphous silicon layer and another dielectric layer sequentially stacked on the second surface 119 of the crystalline silicon layer 110.

In some implementations, since the semiconductor device 100 includes an amorphous silicon layer 120 configured to relieve or distribute stress and a dielectric layer 130 configured to suppress warpage, defects of the semiconductor device 100 due to warpage may be reduced and the reliability of the semiconductor device 100 may be improved.

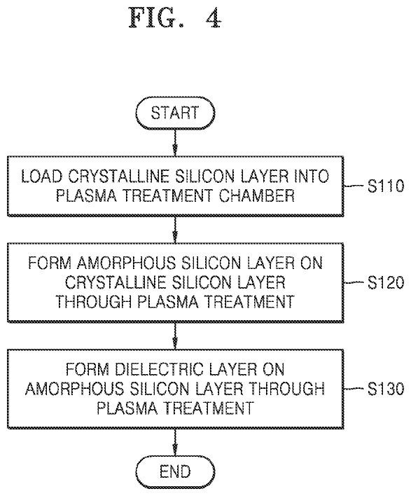

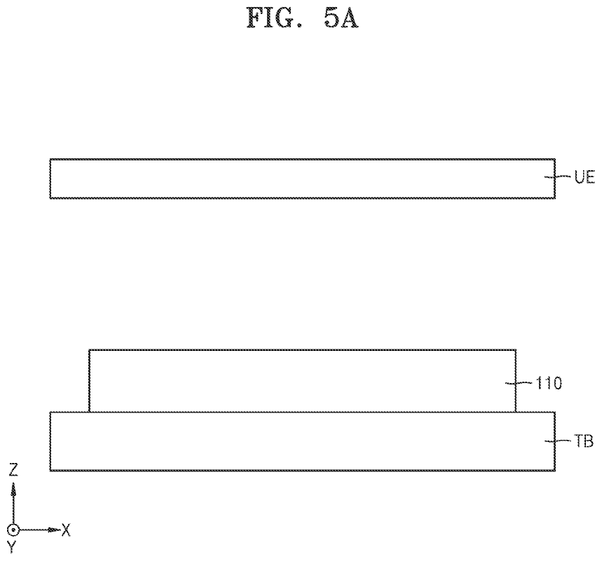

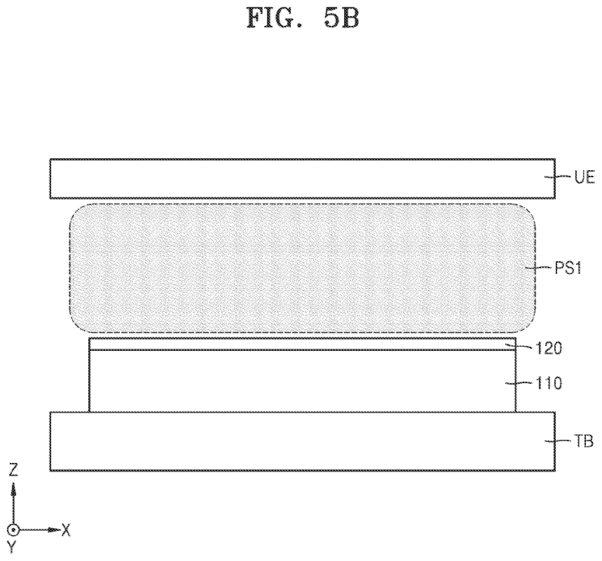

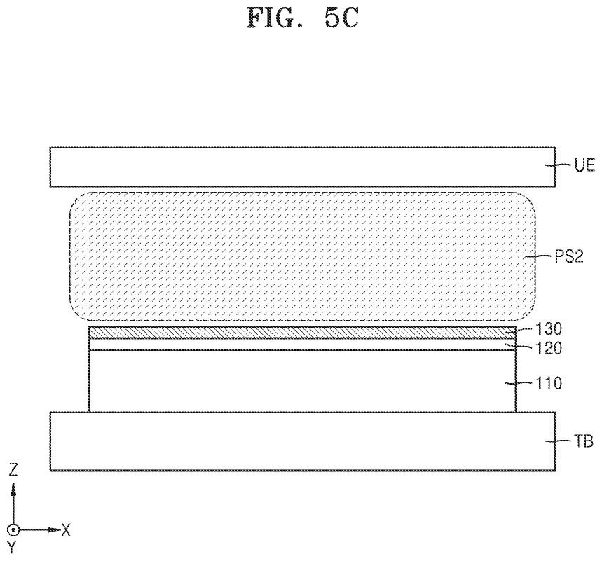

FIG. 4 is a flowchart illustrating an example of a manufacturing method of the semiconductor device 100. FIGS. 5A to 5C are cross-sectional views illustrating an example of a method of manufacturing the semiconductor device 100. Hereinafter, a method of manufacturing the semiconductor device 100 of FIG. 1 is described with reference to FIGS. 4 and 5A to 5C.

Referring to FIG. 5A, a crystalline silicon layer 110 is loaded into a plasma treatment chamber in operation S110.

The crystalline silicon layer 110 may be a substrate formed from a wafer. The crystalline silicon layer 110 may be mounted on a support table TB in a plasma treatment chamber. For example, the support table TB may include an electrostatic chuck configured to fix the crystalline silicon layer 110 with an electro-static force. The support table TB may include an electrode for generating plasma.

Referring to FIG. 5B, an amorphous silicon layer 120 is formed on the crystalline silicon layer 110 in operation S120.

The amorphous silicon layer 120 may be formed through a plasma treatment process using a plasma treatment chamber. The amorphous silicon layer 120 may be formed from a portion of the crystalline silicon layer 110 by a plasma treatment process. The plasma treatment process may include supplying a source gas including argon into a plasma treatment chamber, and generating the first plasma PS1 from a source gas by applying power to at least one of an upper electrode UE provided in the plasma treatment chamber and an electrode of the support table TB. The plasma treatment process may include a sputtering process using the first plasma PS1. Argon ions in the first plasma PS1 may be incident on the crystalline silicon layer 110, and the amorphous silicon layer 120 may be generated from a portion of the crystalline silicon layer 110 by a reaction between argon ions and the crystalline silicon layer 110. In example implementations, to adjust the thickness of the amorphous silicon layer 120, plasma treatment time, RF power, plasma concentration, and the like may be adjusted.

Referring to FIG. 5C, a dielectric layer 130 is formed on the amorphous silicon layer 120 in operation S130.

The dielectric layer 130 may be formed through a plasma treatment process using a plasma treatment chamber. The plasma treatment process may include supplying a source gas including an oxygen-source gas including an oxygen element and a nitrogen-source gas including a nitrogen element into a plasma treatment chamber, and generating the second plasma PS2 from a source gas by applying power to at least one of an upper electrode UE provided in the plasma treatment chamber and an electrode of the support table TB. A nitrogen component and an oxygen component in the second plasma PS2 may react with a portion of the amorphous silicon layer 120 to form a dielectric layer 130 including silicon oxynitride. In example implementations, to adjust the thickness of the dielectric layer 130, plasma treatment time, RF power, plasma concentration, and the like may be adjusted.

In example implementations, the source gas used to perform the plasma treatment process for forming the dielectric layer 130 may include a gas selected from the group consisting of N₂, NO, N₂O₂, N₃, NH₃, He, Ar, H₂, O₂, CO, CO₂, and a mixture thereof.

In example implementations, to adjust the ratio of an oxygen element and a nitrogen element in the silicon oxynitride of the dielectric layer 130, in the plasma treatment process for forming the dielectric layer 130, a ratio between the flow rate of the nitrogen-source gas and the flow rate of the oxygen-source gas introduced into the plasma treatment chamber may be adjusted.

In example implementations, the plasma treatment process for forming the dielectric layer 130 and the plasma treatment process for forming the amorphous silicon layer 120 may be performed in-situ in the same plasma treatment chamber.

After forming the dielectric layer 130, the semiconductor device including the crystalline silicon layer 110, the amorphous silicon layer 120, and the dielectric layer 130 is unloaded from the plasma treatment chamber.

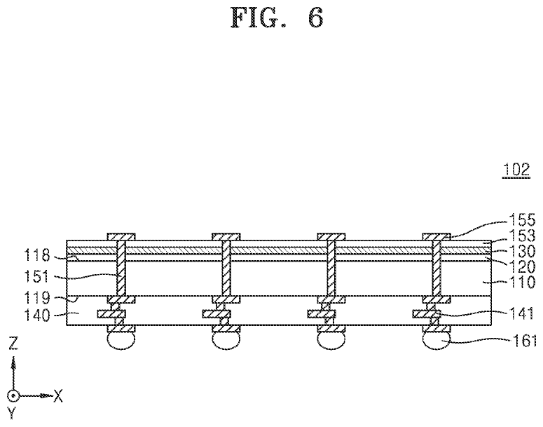

FIG. 6 is a cross-sectional view illustrating an example of a semiconductor device 102. Hereinafter, the semiconductor device 102 shown in FIG. 6 will be described, focusing on the differences from the semiconductor device 100 described with reference to FIG. 1.

Referring to FIG. 6, the semiconductor device 102 may include a crystalline silicon layer 110, an amorphous silicon layer 120, a dielectric layer 130, an interconnect structure 140, a back passivation layer 153, a through electrode 151, and a connection bump 161.

An interconnect structure 140 may be disposed under the crystalline silicon layer 110. The interconnect structure 140 may include a back end of line (BEOL) structure. The interconnect structure 140 may include an insulating layer extending along the second surface 119 of the crystalline silicon layer 110 and conductive wiring patterns 141 provided in the insulating layer. The wiring patterns 141 may include bump pads connected to the connection bumps 161 provided below the interconnect structure 140. The connection bump 161 may be formed of, for example, solder. The wiring pattern 141 may include, for example, a metal, such as copper (Cu), aluminum (Al), tungsten (W), titanium (Ti), tantalum (Ta), indium (In), molybdenum (Mo), manganese (Mn), cobalt (Co), tin (Sn), Nickel (Ni), magnesium (Mg), rhenium (Re), beryllium (Be), gallium (Ga), ruthenium (Ru), and the like, or an alloy thereof.

The back passivation layer 153 may be disposed on the dielectric layer 130 and conformally extend along an upper surface of the dielectric layer 130. The back passivation layer 153 may include, for example, an insulating polymer, a silicon oxide layer, a silicon nitride layer, or a combination thereof. An upper conductive pad 155 may be disposed on the back passivation layer 153.

The through electrode 151 may vertically penetrate the crystalline silicon layer 110, the amorphous silicon layer 120, the dielectric layer 130, and the back passivation layer 153. The through electrode 151 may have a columnar shape extending in the vertical direction (Z direction). The upper end of the through electrode 151 may be connected to the upper conductive pad 155, and the lower end of the through electrode 151 may be connected to the wiring pattern 141 of the interconnect structure 140. The through electrode 151 may electrically connect the wiring pattern 141 of the interconnect structure 140 to the upper conductive pad 155. In example implementations, the top of the sidewall of the through electrode 151 may be surrounded by the back passivation layer 153, and the top surface of the through electrode 151 may be coplanar with the top surface of the back passivation layer 153.

In example implementations, the semiconductor device 102 may be a memory semiconductor chip. The memory semiconductor chip may be, for example, a volatile memory semiconductor chip such as a dynamic random access memory (DRAM) chip or a static random access memory (SRAM) chip, or may be a non-volatile memory semiconductor chip such as a phase-change random access memory (PRAM) chip, a magnetoresistive random access memory (MRAM) chip, a ferroelectric random access memory (FeRAM) chip, or a resistive random access memory (RRAM) chip. In some implementations, the semiconductor device 102 may be a High Bandwidth Memory (HBM) DRAM semiconductor chip.

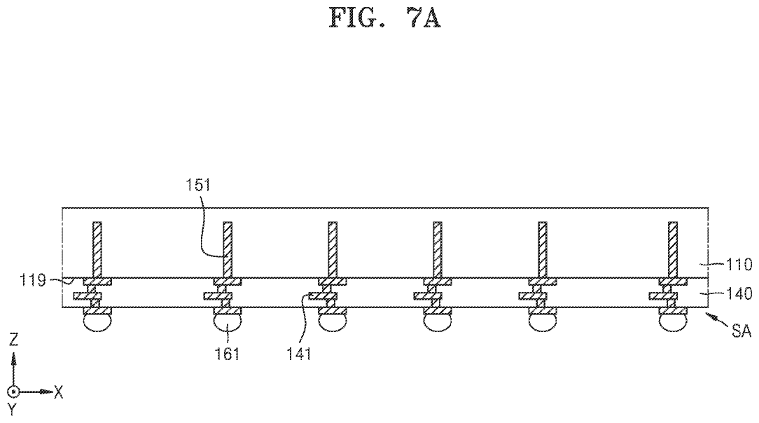

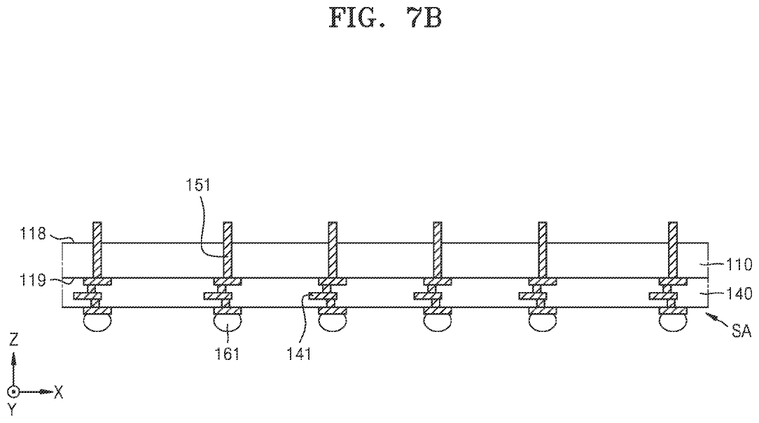

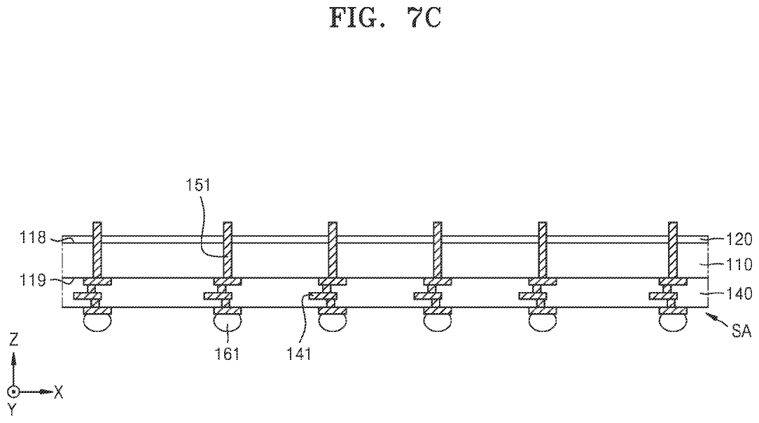

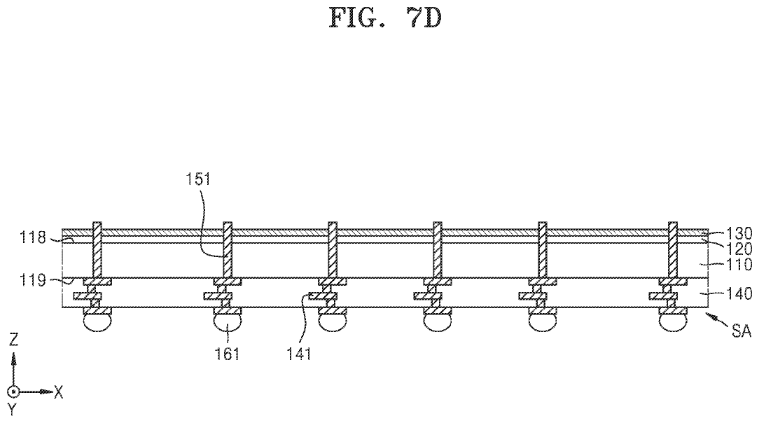

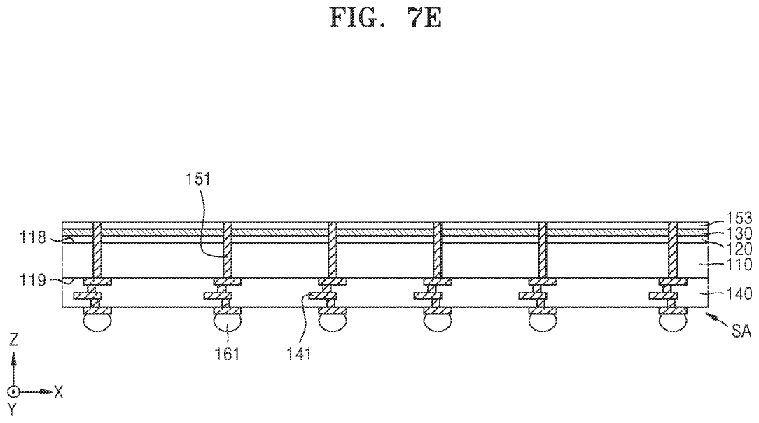

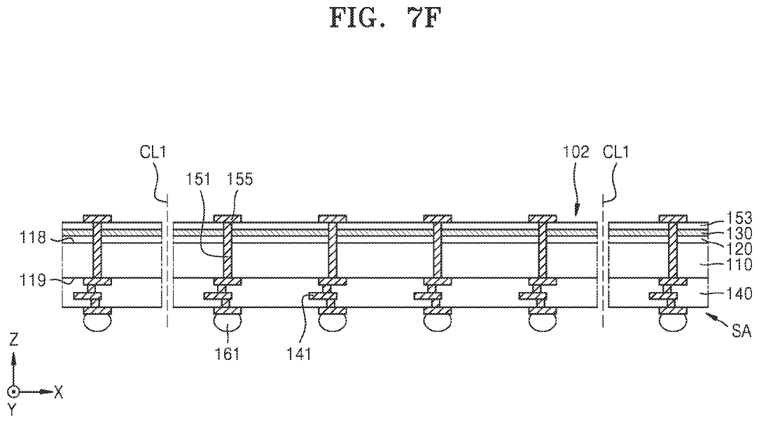

FIGS. 7A to 7F are cross-sectional views illustrating another example of a method of manufacturing the semiconductor device 102. Hereinafter, an exemplary manufacturing method of the semiconductor device 102 shown in FIG. 6 will be described with reference to FIGS. 7A to 7F.

Referring to FIG. 7A, a structure SA having a crystalline silicon layer 110, an interconnect structure 140 on the second surface 119 of the crystalline silicon layer 110, and a through electrode 151 in the crystalline silicon layer 110 is prepared.

Referring to FIGS. 7A and 7B, a through electrode 151 is exposed by removing a portion of the crystalline silicon layer 110. As a portion of the crystalline silicon layer 110 is removed, the thickness of the crystalline silicon layer 110 is reduced, and a portion of the through electrode 151 protrudes from the first surface 118 of the crystalline silicon layer 110. To remove a portion of the crystalline silicon layer 110, an etch-back process, a chemical mechanical polishing (CMP) process, or a combination thereof may be used.

Referring to FIG. 7C, an amorphous silicon layer 120 is formed on the first surface 118 of the crystalline silicon layer 110. The amorphous silicon layer 120 may be formed through substantially the same method as the method of forming the amorphous silicon layer 120 described above with reference to FIG. 5B.

Referring to FIG. 7D, a dielectric layer 130 is formed on the amorphous silicon layer 120. The dielectric layer 130 may be formed through substantially the same method as the formation method of the dielectric layer 130 described above with reference to FIG. 5C.

Referring to FIG. 7E, a back passivation layer 153 covering the dielectric layer 130 is formed. To form the back passivation layer 153, after the insulating layer covering the dielectric layer 130 and the through electrode 151 is formed, a portion of the insulating layer may be removed to expose the through electrode 151.

Referring to FIG. 7F, an upper conductive pad 155 connected to the through electrode 151 is formed on the back passivation layer 153. After forming the upper conductive pad 155, the structure SA is cut along the cutting line CL1 to separate the structure SA into a plurality of semiconductor devices 102.

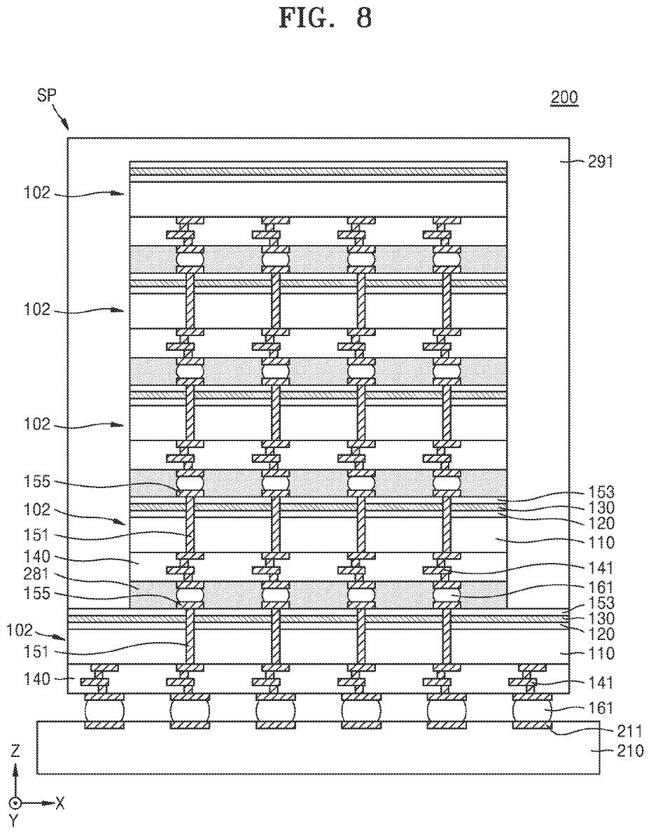

FIG. 8 is a cross-sectional view illustrating another example of a semiconductor package 200.

Referring to FIG. 8, the semiconductor package 200 may include a package substrate 210 and a sub-package SP mounted on the package substrate 210.

The package substrate 210 may be an interposer substrate or a printed circuit board. The package substrate 210 may include an upper connection pad 211.

The sub-package SP may include a plurality of semiconductor devices 102, a gap-fill insulating layer 281, and a molding layer 291. Each of the plurality of semiconductor devices 102 may be substantially the same as or similar to the semiconductor device 102 described with reference to FIG. 6. The uppermost semiconductor device 102 among the plurality of semiconductor devices 102 may not include the through electrode 151. The horizontal width of the lowermost semiconductor device 102 among the plurality of semiconductor devices 102 may be greater than that of other semiconductor devices 102. The lowermost semiconductor device 102 may further extend outward from sidewalls of the other semiconductor devices 102.

A plurality of semiconductor devices 102 may be stacked in the vertical direction (Z direction). In the sub-package SP, the plurality of semiconductor devices 102 may be electrically connected to each other through connection bumps 161. The lowermost semiconductor device 102 may be electrically and physically connected to the upper connection pad 211 of the package substrate 210 through the connection bump 161. The plurality of semiconductor devices 102 may be electrically connected to other semiconductor chips mounted on the package substrate 210 through the package substrate 210.

The gap-fill insulating layer 281 may fill a gap between two semiconductor devices 102 adjacent in a vertical direction (Z direction) among the plurality of semiconductor devices 102 and may surround the connection bumps 161. The gap-fill insulating layer 281 may be formed from an underfill material or a non-conductive film.

The sub-package SP may include a molding layer 291 covering the semiconductor devices 102. The molding layer 291 may be provided on the lowermost semiconductor device 102 and may surround other semiconductor devices 102 excluding the lowermost semiconductor device 102 among the plurality of semiconductor devices 102. The molding layer 291 may include an epoxy molding compound.

In some implementations, since each of the plurality of semiconductor devices 102 includes an amorphous silicon layer 120 configured to relieve or distribute stress and a dielectric layer 130 configured to suppress warpage, defects of the plurality of semiconductor devices 102 due to warpage may be reduced. Accordingly, the reliability of the semiconductor package 200 including the plurality of semiconductor devices 102 may be improved.

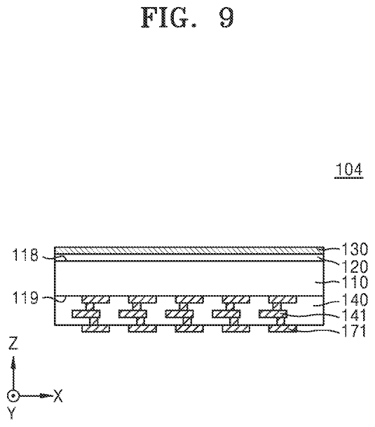

FIG. 9 is a cross-sectional view illustrating another example of a semiconductor device 104. Hereinafter, the semiconductor device 104 shown in FIG. 9 will be described, focusing on the differences from the semiconductor devices 100 and 102 described with reference to FIGS. 1 and 6.

Referring to FIG. 9, a semiconductor device 104 may include a crystalline silicon layer 110, an amorphous silicon layer 120, a dielectric layer 130, and an interconnect structure 140. The amorphous silicon layer 120 may be provided on the first surface 118 of the crystalline silicon layer 110 and cover the second surface 119 of the crystalline silicon layer 110. The dielectric layer 130 may be provided on the amorphous silicon layer 120 and cover the amorphous silicon layer 120. The interconnect structure 140 may be disposed on the second surface 119 of the crystalline silicon layer 110. The interconnect structure 140 may include a BEOL structure. The interconnect structure 140 may include an insulating layer and conductive wiring patterns 141 provided in the insulating layer. The conductive wiring patterns 141 may include conductive connection pads 171 provided below the interconnect structure 140.

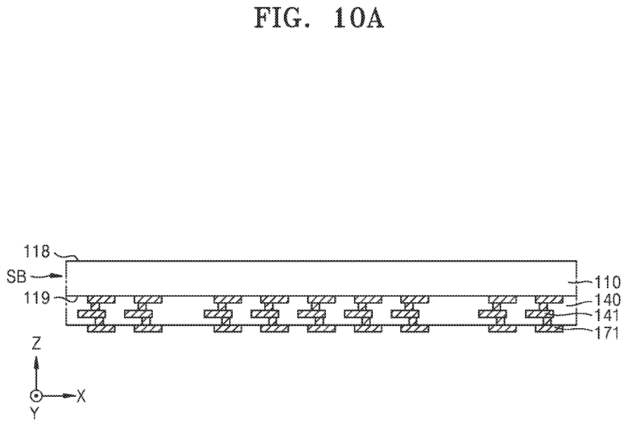

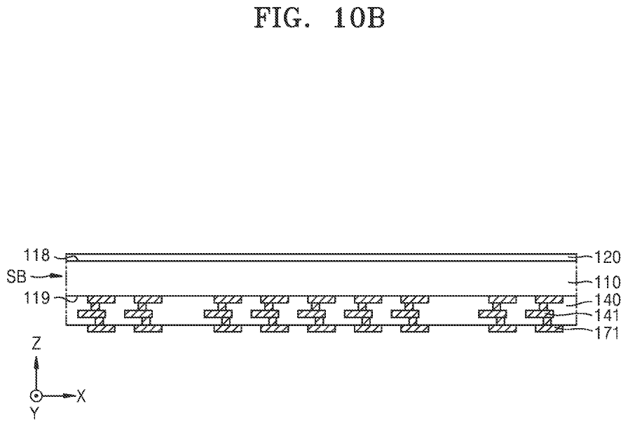

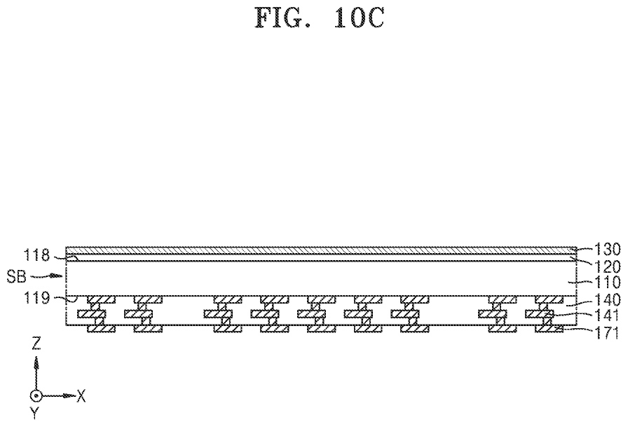

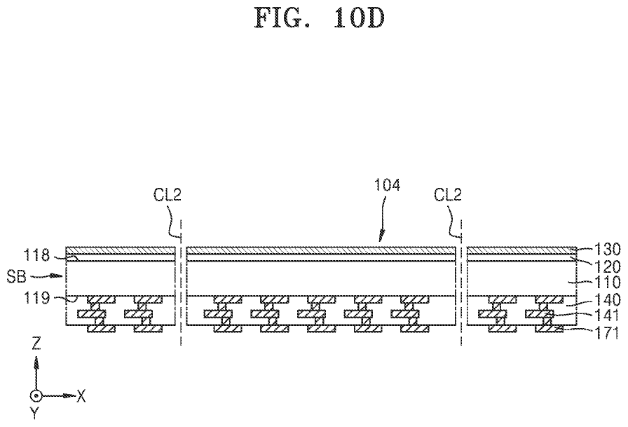

FIGS. 10A to 10D are cross-sectional views illustrating another example of a method of manufacturing a semiconductor device 104. Hereinafter, an exemplary manufacturing method of the semiconductor device 104 shown in FIG. 9 will be described with reference to FIGS. 10A to 10D.

Referring to FIG. 10A, a structure SB having a crystalline silicon layer 110 and an interconnect structure 140 on the second surface 119 of the crystalline silicon layer 110 is prepared.

Referring to FIG. 10B, an amorphous silicon layer 120 is formed on the first surface 118 of the crystalline silicon layer 110. The amorphous silicon layer 120 may be formed through substantially the same method as the method of forming the amorphous silicon layer 120 described above with reference to FIG. 5B.

Referring to FIG. 10C, a dielectric layer 130 is formed on the amorphous silicon layer 120. The dielectric layer 130 may be formed through substantially the same method as the formation method of the dielectric layer 130 described above with reference to FIG. 5C.

Referring to FIG. 10D, after forming the dielectric layer 130, the structure SB is cut along the cutting line CL2 to separate the structure SB into a plurality of semiconductor devices 104.

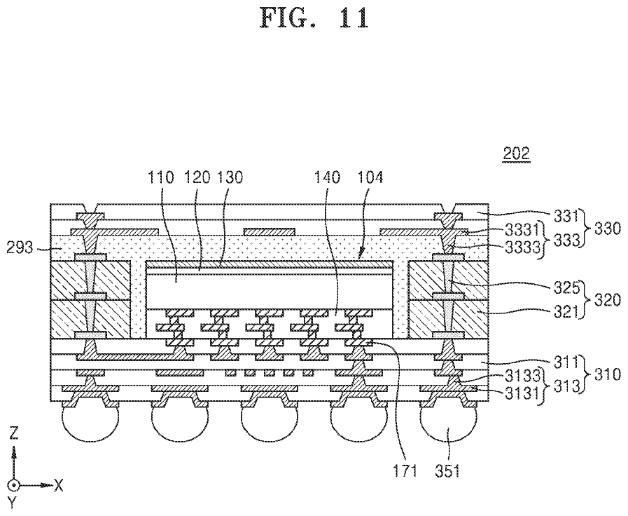

FIG. 11 is a cross-sectional view illustrating another example of a semiconductor package 202.

Referring to FIG. 11, a semiconductor package 202 may include a first redistribution structure 310, a semiconductor device 104, a connection substrate 320, a molding layer 293, and a second redistribution structure 330. The semiconductor package 202 may be a fan-out wafer level package or a fan-out panel level package.

The first redistribution structure 310 may include a plurality of first redistribution insulating layers 311 and first redistribution patterns 313. The first redistribution structure 310 may be referred to as a package substrate or a lower redistribution structure.

The plurality of first redistribution insulating layers 311 may be mutually stacked in the vertical direction (Z direction). The plurality of first redistribution insulating layers 311 may be formed of an insulating polymer, epoxy, or a combination thereof.

The first redistribution patterns 313 may include the first conductive layers 3131 extending in the horizontal direction (X direction and/or Y direction) within the first redistribution insulating layer 311, and the first redistribution insulating layer 311 may include first conductive via patterns 3133 extending in the vertical direction (Z direction). Each of the first conductive layers 3131 may extend along one of upper and lower surfaces of each of the plurality of first redistribution insulating layers 311. The first conductive layers 3131 may be disposed at different vertical levels to form a multilayer structure. Each of the first conductive via patterns 3133 may pass through at least one layer of the plurality of first redistribution insulating layers 311. The first conductive via patterns 3133 may electrically connect first conductive layers 3131 to each other disposed at different vertical levels. The first redistribution patterns 313 may include external bump pads extending along the surface of the lowermost first redistribution insulating layer 311 among the plurality of first redistribution insulating layers 311. The external bump pad may be connected to the external connection terminal 351. The external connection terminals 351 may be formed from, for example, solder balls or solder bumps. The first redistribution patterns 313 may include, for example, a metal, such as copper (Cu), aluminum (Al), tungsten (W), titanium (Ti), tantalum (Ta), indium (In), molybdenum (Mo), manganese (Mn), cobalt (Co), tin (Sn), Nickel (Ni), magnesium (Mg), rhenium (Re), beryllium (Be), gallium (Ga), ruthenium (Ru), and the like, or an alloy thereof.

The semiconductor device 104 may be disposed on the first redistribution structure 310. The semiconductor device 104 may be substantially the same as or similar to the semiconductor device 104 described with reference to FIG. 9. The interconnect structure 140 of the semiconductor device 104 may contact the first redistribution structure 310. The conductive connection pad 171 of the semiconductor device 104 may be connected to the first redistribution pattern 313.

A connection substrate 320 may be disposed on the first redistribution structure 310. The connection substrate 320 may be disposed around the semiconductor device 104 and provide an accommodation space for accommodating the semiconductor device 104. The connection substrate 320 may include an insulating panel body 321 and a vertical connection conductor 325. In example implementations, the connection substrate 320 may be a multi-layer printed circuit board (PCB). The vertical connection conductor 325 may extend in the vertical direction (Z direction) within the connection substrate 320. The vertical connection conductor 325 may be electrically connected to the first redistribution pattern 313. The vertical connection conductor 325 may be electrically connected to the semiconductor device 104 through the first redistribution pattern 313.

In example implementations, the panel body 321 may be omitted, and the vertical connection conductor 325 may be a conductive post directly contacting the molding layer 293 and penetrating the molding layer 293 vertically. In this case, the vertical connection conductor 325 may be disposed in the molding layer 293.

The molding layer 293 may be provided on the first redistribution structure 310 and cover the semiconductor device 104 and the connection substrate 320. A portion of the molding layer 293 is provided within the accommodation space of the connection substrate 320 and may fill a gap between the connection substrate 320 and the semiconductor device 104. The molding layer 293 may be formed from, for example, an epoxy molding compound.

The second redistribution structure 330 may be disposed on the molding layer 293. The second redistribution structure 330 may include a plurality of second redistribution insulating layers 331 and second redistribution patterns 333. The second redistribution structure 330 may be referred to as an upper redistribution structure.

The plurality of second redistribution insulating layers 331 may be mutually stacked in the vertical direction (Z direction). A material of the second redistribution insulating layer 331 may be the same as that of the first redistribution insulating layer 311.

The second redistribution patterns 333 may include second conductive layers 3331 extending in the horizontal direction, and (X direction and/or Y direction), and second conductive via patterns 3333 extending in the vertical direction (Z direction). The second conductive layers 3331 may extend along one surface of the molding layer 293 and upper surfaces of the plurality of second redistribution insulating layers 331. The second conductive layers 3331 may be disposed at different vertical levels to form a multilayer structure. The second conductive via patterns 3333 may pass through at least one of the plurality of second redistribution insulating layers 331. The second conductive via patterns 3333 may electrically connect second conductive layers 3331 to each other disposed at different vertical levels. Some of the second conductive via patterns 3333 may extend within the molding layer 293 and be connected to the vertical connection conductor 325 of the connection substrate 320. A material of the second redistribution pattern 333 may be substantially the same as that of the first redistribution pattern 313. The second redistribution pattern 333 may be electrically connected to the semiconductor device 104 and/or the external connection terminal 351 through an electrical signal path including the vertical connection conductor 325 and the first redistribution patterns 313.

In some implementations, since each of the plurality of semiconductor devices 104 includes an amorphous silicon layer 120 configured to relieve or distribute stress and a dielectric layer 130 configured to suppress warpage, defects of the plurality of semiconductor devices 104 due to warpage may be reduced. Accordingly, the reliability of the semiconductor package 202 including the semiconductor device 102 may be improved.

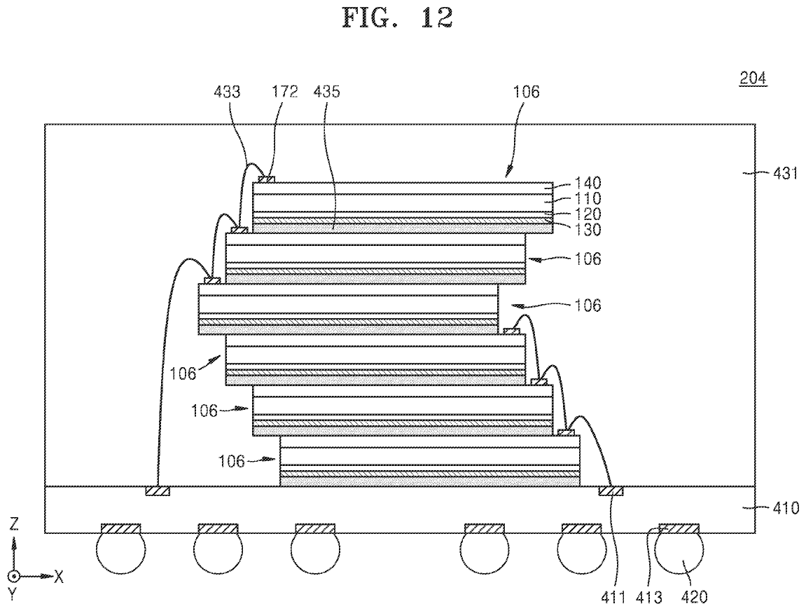

FIG. 12 is a cross-sectional view illustrating another example of a semiconductor package 204.

Referring to FIG. 12, a semiconductor package 204 may include a package substrate 410, and a plurality of semiconductor devices 106, conductive wires 433, and a molding layer 431 provided on the package substrate 410.

The package substrate 410 may include, for example, a printed circuit board (PCB), a flexible board, a tape board, and the like. The package substrate 410 may include an upper connection pad 411 provided on the upper surface of the package substrate 410 and a lower connection pad 413 provided on the lower surface of the package substrate 410, and the lower connection pad 413 may be connected to the external connection terminal 420.

A plurality of semiconductor devices 106 may be stacked in the vertical direction (Z direction). In FIG. 12, the semiconductor package 204 is illustrated as including six semiconductor devices 106 stacked in the vertical direction (Z direction), but the number of semiconductor devices 106 is not limited thereto. For example, the semiconductor package 204 may include seven or more semiconductor devices 106 stacked in the vertical direction (Z direction). In example implementations, the semiconductor device 106 may be a memory semiconductor chip. The memory semiconductor chip may be, for example, a volatile memory semiconductor chip such as DRAM or SRAM, or a non-volatile memory semiconductor chip such as PRAM, MRAM, FeRAM, or RRAM.

A plurality of semiconductor devices 106 may be stacked offset in a lateral direction. In two semiconductor devices 106 adjacent in the vertical direction (Z direction) among the plurality of semiconductor devices 106, the semiconductor device 106 located on the lower side may protrude from the semiconductor device 106 on the upper side in a lateral direction. Among the plurality of semiconductor devices 106, between two semiconductor devices 106 adjacent in the vertical direction (Z direction), an adhesive layer 435 such as a die attach film for fixing the two semiconductor devices 106 may be disposed.

Each semiconductor device 106 may include a crystalline silicon layer 110, an amorphous silicon layer 120 under the crystalline silicon layer 110, a dielectric layer 130 under the amorphous silicon layer 120 and an interconnect structure 140 on the crystalline silicon layer 110. In each semiconductor device 106, the interconnect structure 140 may include a conductive connection pad 172.

The conductive wires 433 may electrically connect the plurality of semiconductor devices 106 to each other or electrically connect the plurality of semiconductor devices 106 to the package substrate 410. The conductive wires 433 may include an inter-chip connection wire extending between the conductive connection pads 172 of the two semiconductor devices 106, and a chip-substrate connection wire extending between the conductive connection pad 172 of any one of the semiconductor devices 106 and the upper connection pad 411 of the package substrate 410.

The molding layer 431 may be provided on the package substrate 410 and cover the plurality of semiconductor devices 106. The molding layer 431 may be formed from, for example, an epoxy molding compound.

In some implementations, since each of the plurality of semiconductor devices 106 includes an amorphous silicon layer 120 configured to relieve or distribute stress and a dielectric layer 130 configured to suppress warpage, defects of the plurality of semiconductor devices 106 due to warpage may be reduced. Accordingly, the reliability of the semiconductor package 204 including the plurality of semiconductor devices 106 may be improved.

While this specification contains many specific implementation details, these should not be construed as limitations on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

While the concepts disclosed herein have been shown and described with reference to implementations thereof, it will be understood that various changes in form and details may be made therein without departing from the spirit and scope of the following claims.

1. A semiconductor device comprising:
a crystalline silicon layer;
an amorphous silicon layer on the crystalline silicon layer and extending along a first surface of the crystalline silicon layer; and
a dielectric layer on the amorphous silicon layer and extending along a surface of the amorphous silicon layer, wherein the dielectric layer includes silicon oxynitride and has compressive stress.

2. The semiconductor device of claim 1, wherein the amorphous silicon layer is in direct contact with the first surface of the crystalline silicon layer,
wherein the dielectric layer is in direct contact with the surface of the amorphous silicon layer, and
wherein the dielectric layer separates from the crystalline silicon layer with the amorphous silicon layer disposed between the dielectric layer and the crystalline silicon layer.

3. The semiconductor device of claim 1, wherein a thickness of the amorphous silicon layer is between about 1 nm and about 200 nm.

4. The semiconductor device of claim 1, wherein a thickness of the dielectric layer is between about 1 nm and about 200 nm.

5. The semiconductor device of claim 1, wherein the dielectric layer comprises at least one of:
a binary compound including a silicon element and a nitrogen element,
a ternary compound including a silicon element, a nitrogen element, and a hydrogen element, and
a quaternary compound including a silicon element, a nitrogen element, an oxygen element, and a hydrogen element.

6. The semiconductor device of claim 1, wherein the dielectric layer does not comprise carbon.

7. The semiconductor device of claim 1, further comprising an interconnect structure contacting a second surface of the crystalline silicon layer and including a wiring pattern, the second surface of the crystalline silicon layer being opposite to the first surface of the crystalline silicon layer.

8. The semiconductor device of claim 7, further comprising a through electrode passing through the crystalline silicon layer, the amorphous silicon layer, and the dielectric layer, and electrically connected to the wiring pattern.

9. A semiconductor package comprising a plurality of semiconductor devices stacked in a vertical direction, wherein each semiconductor device of the plurality of semiconductor devices comprises:
a crystalline silicon layer;
an amorphous silicon layer on the crystalline silicon layer and extending along a first surface of the crystalline silicon layer; and
a dielectric layer on the amorphous silicon layer and extending along a surface of the amorphous silicon layer, wherein the dielectric layer includes silicon oxynitride and has compressive stress.

10. The semiconductor package of claim 9, wherein each semiconductor device of the plurality of semiconductor devices further comprises:
an interconnect structure contacting a second surface of the crystalline silicon layer and including a wiring pattern; and
a through electrode passing through the crystalline silicon layer, the amorphous silicon layer, and the dielectric layer, and electrically connected to the wiring pattern.

11. The semiconductor package of claim 9, wherein, among the plurality of semiconductor devices, two neighboring semiconductor devices in the vertical direction are stacked offset in a lateral direction, and
wherein the plurality of semiconductor devices are electrically connected through conductive wires.

12. The semiconductor package of claim 9, wherein each semiconductor device of the plurality of semiconductor devices is a memory chip.

13. The semiconductor package of claim 9, wherein a thickness of the amorphous silicon layer is between about 1 nm and about 200 nm, and
wherein a thickness of the dielectric layer is between about 1 nm and about 200 nm.

14. The semiconductor package of claim 9, wherein the dielectric layer comprises at least one of:
a binary compound including a silicon element and a nitrogen element,
a ternary compound including a silicon element, a nitrogen element, and a hydrogen element, and
a quaternary compound including a silicon element, a nitrogen element, an oxygen element, and a hydrogen element.

15. The semiconductor package of claim 9, wherein the dielectric layer does not comprise carbon.

16. A semiconductor package comprising:
a first redistribution structure including a first redistribution pattern;
a semiconductor device on the first redistribution structure;
a molding layer disposed on the first redistribution structure and configured to cover the semiconductor device;
a second redistribution structure disposed on the molding layer and including a second redistribution pattern; and
a vertical connection conductor electrically connecting the first redistribution pattern to the second redistribution pattern,
wherein the semiconductor device comprises:
a crystalline silicon layer having a first surface and a second surface opposite to the first surface, the second surface facing the first redistribution structure;
an amorphous silicon layer on the crystalline silicon layer, extending along the first surface of the crystalline silicon layer, and contacting the first surface of the crystalline silicon layer;
a dielectric layer on the amorphous silicon layer and extending along a surface of the amorphous silicon layer, wherein the dielectric layer includes silicon oxynitride and has compressive stress; and
an interconnect structure between the second surface of the crystalline silicon layer and the first redistribution structure, wherein the interconnect structure includes a wiring pattern.

17. The semiconductor package of claim 16, wherein a thickness of the amorphous silicon layer is between about 1 nm and about 200 nm, and
wherein a thickness of the dielectric layer is between about 1 nm and about 200 nm.

18. The semiconductor package of claim 16, wherein the dielectric layer comprises at least one of:
a binary compound including a silicon element and a nitrogen element,
a ternary compound including a silicon element, a nitrogen element, and a hydrogen element, and
a quaternary compound including a silicon element, a nitrogen element, an oxygen element, and a hydrogen element.

19. The semiconductor package of claim 16, wherein the dielectric layer does not comprise carbon.

20. The semiconductor package of claim 16, wherein the amorphous silicon layer entirely covers the first surface of the crystalline silicon layer,
wherein the dielectric layer entirely covers the amorphous silicon layer, and
wherein the dielectric layer separates from the crystalline silicon layer with the amorphous silicon layer disposed between the dielectric layer and the crystalline silicon layer.

21.-27. (canceled)
